(19) United States
(12) Patent Application Publication
(10) Pub. No.: US 2017/0153172 A1
(43) Pub. Date: Jun. 1, 2017

(54) PARTICLE CONCENTRATION MECHANISM, PARTICLE MEASURING DEVICE, AND SUBSTRATE PROCESSING APPARATUS INCLUDING PARTICLE MEASURING DEVICE

(71) Applicant: TOKYO ELECTRON LIMITED, Tokyo (JP)

(72) Inventor: Kyoko IKEDA, Yamanashi (JP)

(21) Appl. No.: 15/359,936

(22) Filed: Nov. 23, 2016

(30) Foreign Application Priority Data
Nov. 26, 2015 (JP) 2015-230403

(51) Int. Cl. G01N 15/06; H01J 37/32; B03C 3/49; B03C 3/02; B01D 53/32

(52) U.S. Cl. CPC G01N 15/0656; B03C 3/02; B01D 53/323; B03C 3/49; H01J 37/32981; H01J 37/32834; H01J 37/3244; H01J 2237/053; H01J 2237/334

(57) ABSTRACT

A particle concentration mechanism including: a hollow member made of a conductor and having a space therein, through which the particles in a charged state flow together with a gas; a particle collecting nozzle made of a conductor which is inserted into the space within the hollow member and configured to collect the charged particles within the hollow member; an insulating member configured to insulate the hollow member from the particle collecting nozzle; and a DC power source configured to apply a DC voltage between the hollow member and the particle collecting nozzle. When the DC voltage is applied between the hollow member and the particle collecting nozzle, an electrostatic force directed to an inlet of the particle collecting nozzle acts on the charged particles within the hollow member, and the particles are guided into the particle collecting nozzle and concentrated.

### CROSS-REFERENCE TO RELATED APPLICATIONS

This application is based on and claims priority from Japanese Patent Application No. 2015-230403, filed on Nov. 26, 2015, with the Japan Patent Office, the disclosure of which is incorporated herein in its entirety by reference.

### TECHNICAL FIELD

The present disclosure relates to a particle concentration mechanism, a particle measuring device, and a substrate processing apparatus including the particle measuring device.

### BACKGROUND

A semiconductor manufacturing process includes various processes such as, for example, film-formation, photolithography, and etching. In these processes, a substrate processing apparatus is used in order to perform the processes on a semiconductor substrate. In such a substrate processing apparatus, in terms of improving the yield of products and the accuracy and reliability of the products, it is required to suppress the generation of dust within the substrate processing apparatus, thereby preventing the adhesion of dust (particles) on a semiconductor substrate as much as possible.

Thus, what is requested is a technique for measuring and managing fine particles in real time within a chamber inside the substrate processing apparatus.

As a particle measuring instrument configured to measure particles, an optical particle measuring instrument is generally used. The optical particle measuring instrument is configured to measure particles from the degree of scattering of laser light by particles present in a path through which a laser beam passes.

However, when the particles of the substrate processing apparatus are measured by such an optical particle measuring instrument, a sampling flow rate is very small with respect to the total exhaust amount of the substrate processing apparatus. Thus, it is difficult to efficiently measure particles.

In contrast, Japanese Patent Laid-Open Publication No. 2015-114230 discloses a technology of extracting particles in a concentrated state by: charging particles in a gas; introducing the charged particles into a tube that is constituted by connecting two cylinders having portions that form an electrode to each other via an insulating portion; causing the charged particles to converge on a central axis portion of the tube by an electrostatic field generated within the tube in a state where a high voltage is applied to one electrode and a low voltage is applied to the other electrode; and collecting the converging particles by a collecting nozzle. Thus, it becomes possible to efficiently measure particles.

### SUMMARY

The present disclosure provides a particle concentration mechanism including: a hollow member made of a conductor and having a space therein to which a gas containing particles is guided, and through which the particles in a charged state flow together with the gas; a particle collecting nozzle made of a conductor which is inserted into the space within the hollow member and configured to collect the charged particles within the hollow member together with the gas; an insulating member configured to insulate the hollow member from the particle collecting nozzle; and a DC voltage applying unit configured to apply a DC voltage between the hollow member and the particle collecting nozzle. When the DC voltage applying unit applies the DC voltage between the hollow member and the particle collecting nozzle, an electrostatic force directed to an inlet of the particle collecting nozzle acts on the charged particles within the hollow member, and the particles in the hollow member are guided into the particle collecting nozzle and concentrated.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 a sectional view schematically illustrating an example of a particle concentration mechanism according to a first exemplary embodiment of the present disclosure.

FIG. 2 is a diagram illustrating a simulation result of a potential distribution within a hollow member and a particle collecting nozzle in the particle concentration mechanism according to the first exemplary embodiment of the present disclosure by fluid analysis software.

FIG. 3 is a view illustrating a simulation result of a flow and a flow velocity of negatively charged particles in the first exemplary embodiment of the present disclosure using fluid analysis software.

FIG. 4 is a view illustrating a simulation result of a potential distribution in the method disclosed in Japanese Laid-Open Publication No. 2015-114230 using fluid analysis software.

FIG. 5 is a view illustrating a simulation result of a flow and a flow velocity of negatively charged particles in the method disclosed in Japanese Laid-Open Publication No. 2015-114230 using fluid analysis software.

FIG. 6 is a sectional view schematically illustrating an example of a particle measuring device according to a second exemplary embodiment of the present disclosure.

FIG. 7 is a sectional view schematically illustrating a first example of a substrate processing apparatus according to a third exemplary embodiment of the present disclosure.

FIG. 8 is a sectional view schematically illustrating a second example of the substrate processing apparatus according to the third exemplary embodiment of the present disclosure.

FIG. 9 is a sectional view schematically illustrating a third example of the substrate processing apparatus according to the third exemplary embodiment of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In the technology disclosed in Japanese Patent Laid-Open Publication No. 2015-114230, installation may be limited due to a restriction on a shape. Also, in the technology disclosed in Japanese Patent Laid-Open Publication No. 2015-114230, particles may be concentrated at a relatively high concentration rate. However, it is required to concentrate particles a higher concentration rate so that the particles are measured with a higher efficiency and accuracy.

Accordingly, an object of the present disclosure is to provide a particle concentration mechanism having a reduced shape limitation and a high particle concentration rate, and a particle measuring device including the particle concentration mechanism. Also, the present disclosure provides a substrate processing apparatus equipped with the particle measuring device including the particle concentration mechanism.

In order to solve the above described problems, according to a first aspect of the present disclosure, there is provided a particle concentration mechanism including: a hollow member made of a conductor and having a space therein to which a gas containing particles is guided, and through which the particles in a charged state flow together with the gas; a particle collecting nozzle made of a conductor which is inserted into the space within the hollow member and configured to collect the charged particles within the hollow member together with the gas; an insulating member configured to insulate the hollow member from the particle collecting nozzle; and a DC voltage applying unit configured to apply a DC voltage between the hollow member and the particle collecting nozzle. When the DC voltage applying unit applies the DC voltage between the hollow member and the particle collecting nozzle, an electrostatic force directed to an inlet of the particle collecting nozzle acts on the charged particles within the hollow member, and the particles in the hollow member are guided into the particle collecting nozzle and concentrated.

A voltage of the particle collecting nozzle may be constant throughout the particle collecting nozzle. The particle collecting nozzle may be formed in a tubular shape to be parallel to the hollow member, and have an opening provided to be perpendicular to a flow of the gas in the hollow member. The particle collecting nozzle may be arranged along a central axis of the hollow member.

The charged particles flowing in the space within the hollow member together with the gas may be negatively charged particles, and the DC voltage applying unit may apply a low voltage to the hollow member, and a high voltage to the particle collecting nozzle.

According to a second aspect of the present disclosure, there is provided a particle measuring device including: a hollow member made of a conductor and having a space therein to which a gas containing particles is guided, and through which the particles in a charged state flow together with the gas; a particle collecting nozzle made of a conductor which is inserted into the space within the hollow member and configured to collect the charged particles within the hollow member together with the gas; an insulating member configured to insulate the hollow member from the particle collecting nozzle; a DC voltage applying unit configured to apply a DC voltage between the hollow member and the particle collecting nozzle; and a particle measuring instrument connected to the particle collecting nozzle to measure the particles collected by the particle collecting nozzle. When the DC voltage applying unit applies the DC voltage between the hollow member and the particle collecting nozzle, an electrostatic force directed to an inlet of the particle collecting nozzle acts on the charged particles within the hollow member, and the particles in the hollow member are guided into the particle collecting nozzle and concentrated, and then the concentrated particles are measured by the particle measuring instrument.

In the second aspect, a voltage of the particle collecting nozzle may be constant throughout the particle collecting nozzle. The particle collecting nozzle may be formed in a tubular shape to be parallel to the hollow member, and have an opening provided to be perpendicular to a flow of the gas in the hollow member. The particle collecting nozzle may be arranged along a central axis of the hollow member.

In the second aspect, the charged particles flowing in the space within the hollow member together with the gas may be negatively charged particles, and the DC voltage applying unit may apply a low voltage to the hollow member, and a high voltage to the particle collecting nozzle.

An exhaust flow of a substrate processing apparatus may be introduced into the hollow member. The substrate processing apparatus may be a plasma etching apparatus, an exhaust flow containing negatively charged particles may be introduced into the hollow member, and the DC voltage applying unit may apply a low voltage to the hollow member, and a high voltage to the particle collecting nozzle. The hollow member may constitute a portion of a processing container of the substrate processing apparatus to cause the exhaust flow to directly flow therein. The hollow member may be configured separately from a processing container of the substrate processing apparatus, and may be inserted into the processing container so that the exhaust flow is introduced into the hollow member.

According to a third aspect of the present disclosure, there is provided a substrate processing apparatus including: a processing container configured to accommodate a substrate to be processed therein; a processing gas supply mechanism configured to supply a processing gas into the processing container; an exhaust mechanism configured to exhaust the processing container; and a particle measuring device configured to collect an exhaust flow containing charged particles formed within the processing container exhausted by the exhaust mechanism, and measure the particles. The particle measuring device includes: a hollow member made of a conductor, into which the exhaust flow is introduced; a particle collecting nozzle made of a conductor which is inserted into a space within the hollow member and configured to collect the charged particles within the hollow member together with the gas; an insulating member configured to insulate the hollow member from the particle collecting nozzle; and a DC voltage applying unit configured to apply a DC voltage between the hollow member and the particle collecting nozzle, a particle measuring instrument connected to the particle collecting nozzle to measure the particles collected by the particle collecting nozzle. When the DC voltage applying unit applies the DC voltage between the hollow member and the particle collecting nozzle, an electrostatic force directed to an inlet of the particle collecting nozzle acts on the charged particles within the hollow member, and the particles in the hollow member are guided into the particle collecting nozzle and concentrated, and then the concentrated particles are measured by the particle measuring instrument.

In the third aspect, the exhaust flow may be introduced into the hollow member from the processing container. The substrate processing apparatus may be a plasma etching apparatus, an exhaust flow containing negatively charged particles may be introduced into the hollow member, and the DC voltage applying unit may apply a low voltage to the hollow member, and a high voltage to the particle collecting nozzle. The hollow member may constitute a portion of the processing container to cause the exhaust flow to directly flow therein. The hollow member may be configured separately from the processing container, and may be inserted into the processing container so that the exhaust flow is introduced into the hollow member.

In the third aspect, a placing table configured to place the substrate to be processed thereon may be arranged within the processing container, the processing container includes an annular exhaust space around the placing table, an annular baffle plate is provided above the exhaust space, the particle collecting nozzle is provided in an annular form along the exhaust space above the baffle plate, or provided as a plurality of tubular particle collecting nozzles, and the particle collecting nozzle is sucked toward the particle measuring instrument to have a dust collecting function within the processing container.

In the second and third aspects, as the particle measuring instrument, an LPN or a CNC may be used. A maximum of a ratio of an inner diameter of the hollow member to an inner diameter of the particle collecting nozzle may be determined by a ratio of an exhaust capacity of a pump configured to form the gas stream or the exhaust flow within the hollow member to an exhaust capacity of a pump configured to guide the gas containing the particles to the particle measuring instrument.

According to the present disclosure, when the DC voltage applying unit applies the DC voltage between the hollow member and the particle collecting nozzle, an electrostatic force directed to an inlet of the particle collecting nozzle acts on the charged particles within the hollow member, and the particles in the hollow member are guided into the particle collecting nozzle and concentrated. Thus, a very high concentration rate of particles may be achieved. Also, the hollow member has no limitation in its shape as long as a gas stream accompanied by particles flows within the hollow member. Thus, the hollow member has a very high degree of freedom of installation.

Hereinafter, exemplary embodiments of the present disclosure will be described in detail with reference to the drawings.

### First Exemplary Embodiment

In the first exemplary embodiment, a particle concentration mechanism will be described.

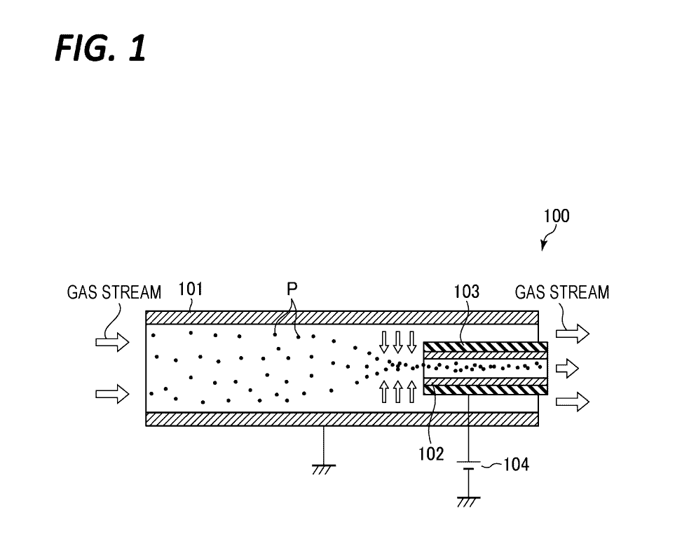

FIG. 1 is a sectional view schematically illustrating an example of a particle concentration mechanism according to the first exemplary embodiment of the present disclosure.

As illustrated in FIG. 1, a particle concentration mechanism 100 according to the present exemplary embodiment is configured to concentrate particles using static electricity in order to efficiently measure the particles with a high accuracy.

The particle concentration mechanism 100 includes: a hollow member 101 made of a conductor and having a space therein to which a gas containing particles P is guided and through which the particles P in a charged state flow together with the gas; a tubular particle collecting nozzle 102 made of a conductor which is inserted into the space within the hollow member 101 and configured to collect the charged particles P within the hollow member 101; an insulating member 103 configured to cover the outside of the particle collecting nozzle 102 to insulate the hollow member 101 from the particle collecting nozzle 102; and a DC power source 104 configured to apply a DC voltage between the hollow member 101 and the particle collecting nozzle 102. The hollow member 101 and the particle collecting nozzle 102 constitute a first electrode and a second electrode which are insulated from each other by the insulating member 103.

As the hollow member 101, any member may be employed as long as it has a space therein to which a gas containing particles P is guided and through which the particles P in a charged state flow together with the gas. The shape of the hollow member 101 is not particularly limited, but may take various shapes such as, for example, a tubular shape, an annular shape, and a container shape. Also, the hollow member 101 may be an independent member, but may constitute a part of a substrate processing apparatus.

For example, a member into which an exhaust flow of a substrate processing apparatus is introduced may be exemplified as the hollow member 101. In this case, a member to be inserted into an exhaust portion of the substrate processing apparatus or a member that constitutes the exhaust portion itself may be suitably exemplified as the hollow member 101. The particles generated by the generation of dust during a substrate processing pass through the exhaust portion of the substrate processing apparatus together with an exhaust flow. Thus, the exhaust portion is suitable for measuring particles.

In the present exemplary embodiment, particles are concentrated using static electricity. Thus, the particles P introduced into an inner space of the hollow member 101 together with a gas flow together with the gas in the charged state. For example, when a substrate processing apparatus to which a particle concentration mechanism 100 is applied is a plasma etching apparatus, particles floating within a chamber are negatively charged due to the influence of plasma. Thus, the negatively charged particles are directly introduced into the hollow member 101. For this reason, a special charging device is unnecessary. Meanwhile, when the introduced particles are not charged, it is required to charge the particles by a suitable charging unit so that the particles flowing within the hollow member 101 are placed in a charged state.

The particle collecting nozzle 102 is inserted into the inner space of the hollow member 101 to collect charged particles P within the hollow member 101. The particle collecting nozzle 102 is configured to collect particles by an electrostatic force as described below, and is formed into, for example, a tubular shape. The inner diameter of the particle collecting nozzle 102 may range from 1 mm to 20 mm, and is, for example, 5 mm. The particle collecting nozzle 102 is thinner than the hollow member 101, and is configured to take in a gas containing particles at a highly lower flow rate than a gas flow rate of the hollow member 101, for example, a flow rate corresponding to about 1/500 of the flow rate of the hollow member 101.

As illustrated in FIG. 1, the particle collecting nozzle 102 is provided in parallel to a gas stream within the hollow member 101, in which the plane of the opening of the particle collecting nozzle 102 is arranged to be perpendicular to the gas stream. Since the particle collecting nozzle 102 is provided in this manner, an area that takes in particles is maximized, and the particles are guided in a direction of the gas stream. Thus, it becomes easy to collect the particles. Also, the particle collecting nozzle 102 is disposed along the central axis of the hollow member 101. This also allows the particles within the hollow member 101 to be easily collected. Meanwhile, in the present exemplary embodiment, since the particles are collected by an electrostatic force, the particle collecting nozzle 102 does not need to be provided as described above. The particle collecting nozzle 102 may sufficiently collect particles even when the particle collecting nozzle 102 is inclined from the gas stream within the hollow member 101 or even when the opening of the particle collecting nozzle 102 is not perpendicular to the stream. The shape of the particle collecting nozzle 102 is not limited to the tubular shape, but may take various shapes. For example, when the shape of the hollow member 101 is a tubular shape, the particle collecting nozzle 102 may also take the tubular shape as described above. For example, when the hollow member 101 is formed in an annular shape, the particle collecting nozzle 102 may be formed in an annular shape.

The DC power source 104 is configured to apply a DC voltage between the hollow member 101 and the particle collecting nozzle 102. A level of the voltage is determined by a charged polarity of the particles P. In the example of FIG. 1, the particles P are negatively charged, and the DC power source 104 applies a voltage between the particle collecting nozzle 102 and the hollow member 101 such that the particle collecting nozzle 102 has a high voltage and the hollow member 101 has a low voltage. In the present example, a positive voltage is applied to the particle collecting nozzle 102, and the hollow member 101 is grounded. Here, a potential difference may range from 100 V to 3000 V, and a voltage applied to the particle collecting nozzle 102 is, for example, 200 V.

On the contrary, when the particles P are positively charged, the DC power source 104 applies a voltage between the particle collecting nozzle 102 and the hollow member 101 such that the particle collecting nozzle 102 has a low voltage and the hollow member 101 has a high voltage.

Since the outside of the particle collecting nozzle 102 is covered with the insulating member 103, an electrostatic force acts on the charged particles when the voltage is applied between the particle collecting nozzle 102 and the hollow member 101 as described above. Specifically, as illustrated in FIG. 1, when the particle collecting nozzle 102 has a high voltage, and the hollow member 101 has a low voltage, a voltage distribution within the space of the hollow member 101 rises steeply at the inlet portion of the particle collecting nozzle 102. Meanwhile, the voltage within the particle collecting nozzle 102 is constant throughout the particle collecting nozzle 102. Accordingly, an electrostatic force directed to the inlet portion of the particle collecting nozzle 102 acts on the negatively charged particles P present within the space of the hollow member 101, and an electrostatic force does not act on the negatively charged particles P within the particle collecting nozzle 102.

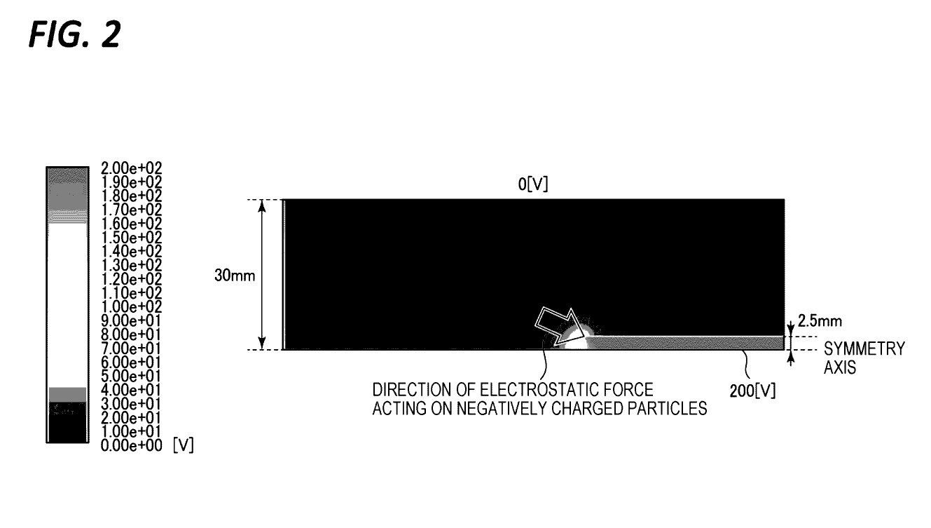

FIG. 2 is a diagram illustrating a simulation result of a potential distribution within the hollow member 101 and the particle collecting nozzle 102 by fluid analysis software. Also, since the potential distribution is vertically symmetrical with respect to the central axis, FIG. 2 illustrates only a region of an upper half portion, with respect to the central axis of the particle collecting nozzle 102.

Here, the illustrated results are obtained in a case where a tube with an inside inner diameter of 60 mm (a radius of 30 mm) is used as the hollow member 101, a tube with an inner diameter of 5 mm (a radius of 2.5 mm) is used as the particle collecting nozzle 102, the particle collecting nozzle 102 is inserted into the center of the hollow member 101, the hollow member 101 is grounded (0 V), and 200 V is applied to the particle collecting nozzle 102.

As illustrated in FIG. 2, a voltage distribution of an electrostatic field within the space of the hollow member 101 steeply rises from 0 V to 200 V in the vicinity of the inlet of the particle collecting nozzle 102, and is constant (200 V) within the particle collecting nozzle 102. Accordingly, an electrostatic force (Coulomb force) directed to the inlet portion of the particle collecting nozzle 102 at a steep gradient acts on the negatively charged particles present within the hollow member 101 as indicated by an arrow. Meanwhile, the inside of the particle collecting nozzle 102 has a constant voltage of 200 V, and thus, an electrostatic force does not act on the inside of the particle collecting nozzle 102.

As described above, since the electrostatic force directed to the inlet portion of the particle collecting nozzle 102 at a steep gradient acts on the negatively charged particles, the negatively charged particles P within the hollow member 101 flow toward the particle collecting nozzle 102, and are efficiently collected by the particle collecting nozzle 102 and concentrated within the particle collecting nozzle 102. Here, most of the negatively charged particles flowing inside the hollow member 101 are guided to the particle collecting nozzle 102 by an electrostatic force without being omitted. Thus, a high concentration rate may be obtained according to a ratio of a flow rate of a gas flowing in the hollow member 101 to a flow rate of a gas flowing in the particle collecting nozzle 102.

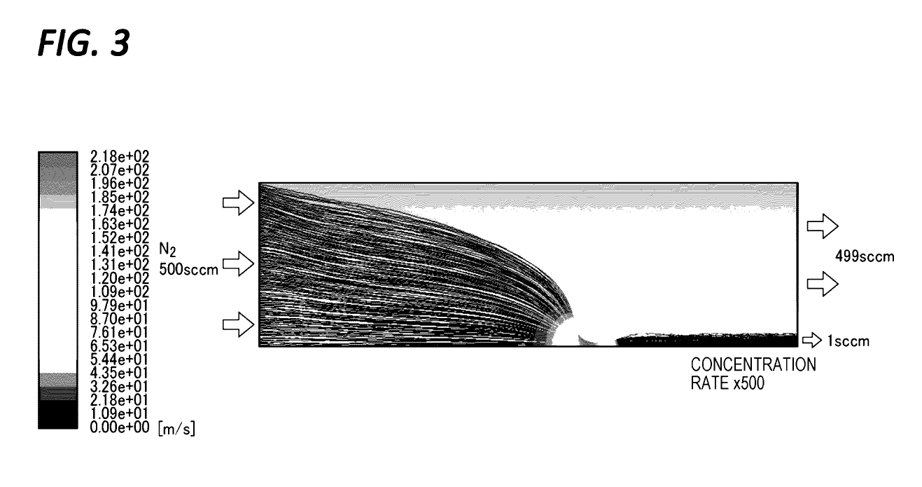

This was confirmed by simulation using fluid analysis software. FIG. 3 is a view illustrating a simulation result of a flow and a flow velocity of negatively charged particles P in the present exemplary embodiment using fluid analysis software. Here, as in the case of FIG. 2, the analysis was made on a case where the hollow member 101 is formed in a tubular shape with an inner diameter of 60 mm, the particle collecting nozzle 102 has an inner diameter of 5 mm, and N₂ gas is caused to flow from one side of the hollow member 101 at a flow rate of 500 sccm, and flow at 1 sccm in the particle collecting nozzle 102. Also, since the flow and the flow velocity of particles are vertically symmetrical with respect to the central axis, FIG. 3 also illustrates only a region of an upper half portion with respect to the central axis of the particle collecting nozzle 102.

As illustrated in FIG. 3, it can be found that most of the negatively charged particles within a gas stream at a flow rate of 500 sccm within the hollow member 101 flow toward the particle collecting nozzle 102, and most of particles are included in a gas stream at 1 sccm flowing in the particle collecting nozzle 102 without being omitted. Also, the flow velocity is extremely high only in the vicinity of the particle collecting nozzle 102. For this reason, as a concentration rate of particles, a high value of 500 times is obtained.

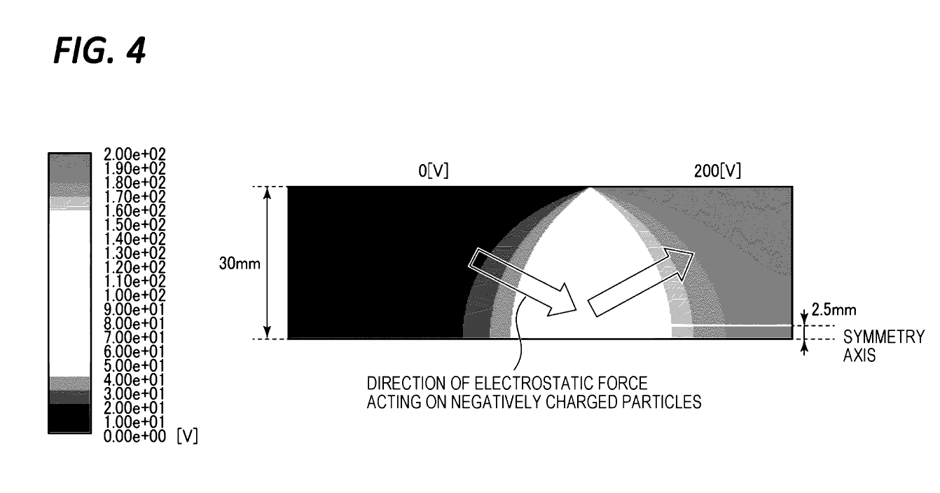

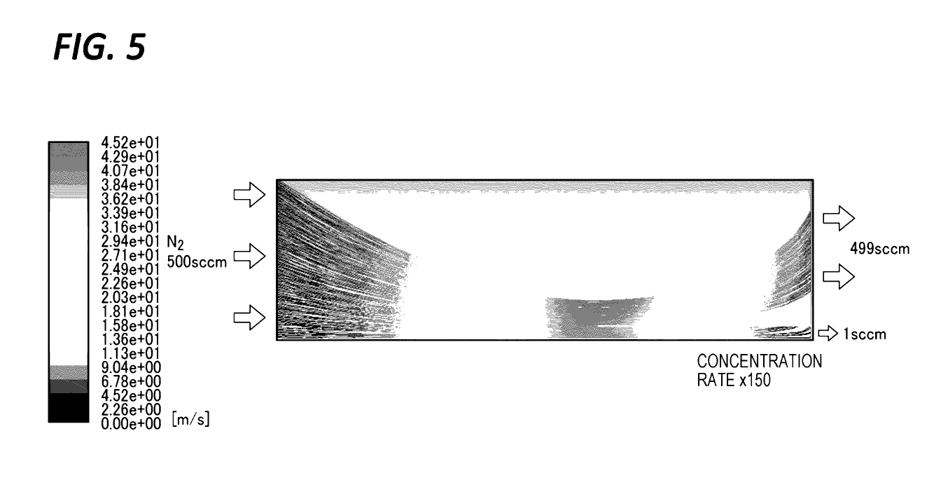

For comparison, simulation results of a potential distribution, a flow and a flow velocity of negatively charged particles P in the method disclosed in Japanese Laid-Open Publication No. 2015-114230, using fluid analysis software are illustrated in FIGS. 4 and 5. In Japanese Laid-Open Publication No. 2015-114230, two cylindrical electrodes made of a conductor are connected via an insulating portion to be formed in a tubular shape, and in a case of negatively charged particles, a low voltage is applied to a first electrode at an upstream side of a gas stream, and a high voltage is applied to a second electrode at a downstream side. Here, the analysis was made on a case where the inner diameter of the tube is 60 mm, 0 V is applied to the first electrode, and 200 V is applied to the second electrode. In this case, it is illustrated that a particle collecting nozzle is inserted into the tube in parallel to a gas stream. Also, in FIG. 5, the analysis was made on a case where a particle collecting nozzle with an inner diameter of 5 mm is inserted into the tube in parallel to a gas stream, and as in a case of FIG. 3, and N₂ gas is caused to flow from one side of the tube at a flow rate of 500 sccm, and flow at 1 sccm in the particle collecting nozzle. Also, since the potential distribution, the flow and the flow velocity of particles are vertically symmetrical with respect to the central axis, FIGS. 4 and 5 also illustrate only a region of an upper half portion with respect to the central axis of the particle collecting nozzle 102.

In the structure of Japanese Laid-Open Publication No. 2015-114230, as illustrated in FIG. 4, when a voltage is applied, a potential difference occurs in an electrostatic field along the direction of a gas stream within the tube. When negatively charged particles flow into the tube, at a region corresponding to the first electrode applied with a low voltage (0 V), an electrostatic force (Coulomb force) is applied in a direction toward the central axis of the tube, and at a region corresponding to the second electrode applied with a high voltage (200 V), the direction of the electrostatic force (Coulomb force) is changed and is directed to the inner surface of the tube. For this reason, the negatively charged particles are focused to have a convergence point on the region of the insulating portion between the first electrode and the second electrode.

As illustrated in FIG. 5, the flow of the negatively charged particles within the tube converges on the central axis along the direction of the electrostatic force (Coulomb force), focused on the convergence point at the region corresponding to the insulating portion, and then diffused in a direction toward the inner surface. In FIG. 5, the particle collecting nozzle with an inner diameter of 5 mm is arranged to have an inlet in the vicinity of the convergence point, and particles are concentrated by the particle collecting nozzle. In the method disclosed in Japanese Laid-Open Publication No. 2015-114230, particles in the N₂ gas at 500 sccm flowing within the tube are concentrated by the particle collecting nozzle, but it can be seen that some of the particles are omitted. The concentration rate is 150 times that is lower than that of the present exemplary embodiment.

As described above, according to the present exemplary embodiment, by adjusting a flow rate of a gas sampled by the particle collecting nozzle 102 in relation to a flow rate of a gas flowing in the hollow member 101, it is possible to obtain a high particle concentration rate of 500 times, which cannot be obtained by the method of Japanese Laid-Open Publication No. 2015-114230.

Also, in the present exemplary embodiment, the hollow member 101 has no limitation in its shape as long as a gas stream accompanied by particles flows within the hollow member 101. Thus, the hollow member 101 has a very high degree of freedom of installation.

Also, since the inside of the particle collecting nozzle 102 has a constant voltage, an electrostatic force does not act on the negatively charged particles within the particle collecting nozzle 102. Thus, particles are hardly attached on the inner wall of the particle collecting nozzle 102. For this reason, most of the collected particles may be measured, and thus, the measurement accuracy is high.

Also, since the hollow member 101 and the particle collecting nozzle 102 which serve as electrodes are not close to each other, a dielectric breakdown of the insulating member 103 hardly occurs.

### Second Exemplary Embodiment

In the second exemplary embodiment, descriptions will be made on a particle measuring device using the particle concentration mechanism of the first exemplary embodiment.

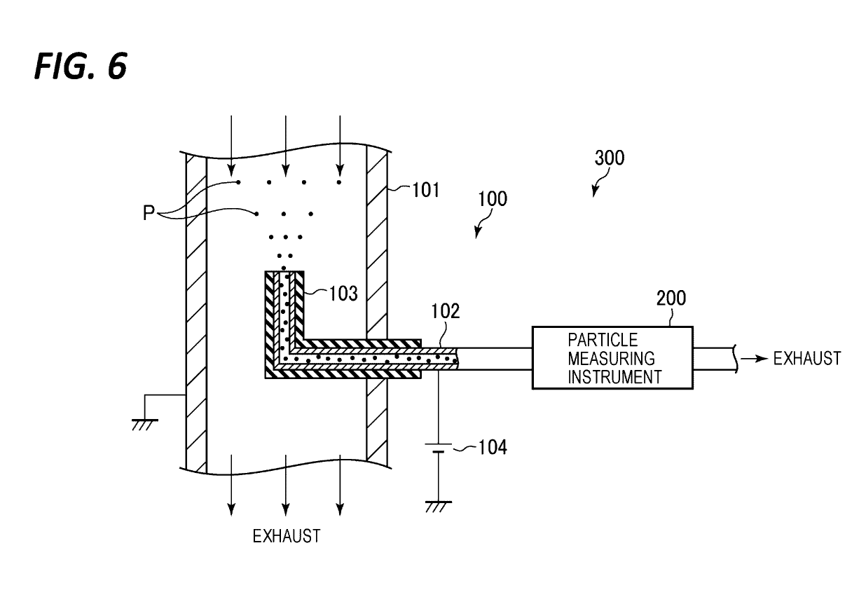

FIG. 6 is a sectional view schematically illustrating an example of a particle measuring device according to the second exemplary embodiment of the present disclosure.

As illustrated in FIG. 6, a particle measuring device 300 according to the second exemplary embodiment includes a particle concentration mechanism 100 having a configuration of the first exemplary embodiment, and a particle measuring instrument 200. In FIG. 6, a hollow member 101 is arranged vertically, and the inside of the hollow member 101 is exhausted downward by an exhaust mechanism (not illustrated). Then, when the inside of the hollow member 101 is exhausted by the exhaust mechanism, a gas stream containing negatively charged particles P is formed from top to bottom in the inner space of the hollow member 101. Then, within the hollow member 101, a particle collecting nozzle 102 is inserted in such a manner that its distal end portion is parallel to the gas stream, that is, vertically. Meanwhile, the distal end portion of the particle collecting nozzle 102 may be inclined to the gas stream.

The particle collecting nozzle 102 is bent to be horizontal, in the middle of the particle collecting nozzle 102, to extend to the outside of the hollow member 101 through the wall portion of the hollow member 101. The particle measuring instrument 200 is connected to the other end of the particle collecting nozzle 102. Then, an exhaust mechanism (not illustrated) is connected at the downstream side of the particle measuring instrument 200, and particles within the hollow member 101 are guided to the particle measuring instrument 200 by the exhaust mechanism.

A DC power source 104 is connected to the particle collecting nozzle 102, the hollow member 101 is grounded, the particle collecting nozzle 102 is applied with a high voltage (e.g., 200 V), and the hollow member 101 is applied with a low voltage (0 V). Also, the outer periphery of a section ranging from the distal end of the particle collecting nozzle 102 to the middle of a portion of the particle collecting nozzle 102 extending from the wall portion of the hollow member 101 to the outside is covered with an insulating member 103.

The particle collecting nozzle 102 is made of a conductor and has a uniform potential in a section from the distal end within the hollow member 101 to the particle measuring instrument 200. Accordingly, particles are prevented from being attached to the inner wall of the particle collecting nozzle 102, and thus may be efficiently measured. Meanwhile, in order to avoid the particle measuring instrument 200 from being applied with a voltage, measures of reducing a voltage in the vicinity of the particle measuring instrument 200 in an appropriate manner may be taken.

As the particle measuring instrument 200, various instruments such as, for example, a laser particle counter (LPC) or a condensation nucleus counter (CNC) that measures sent fine particles after increasing the size of the particles by condensing the particles may be used

Such a particle measuring device 300 may be provided in various forms because the hollow member 101 has a high degree of freedom of shape. Also, since the concentration rate of particles may be increased, most of the particles may be efficiently measured without being omitted.

For example, the particle measuring device of the present exemplary embodiment may be mounted in an exhaust portion of a substrate processing apparatus so as to measure particles included in an exhaust flow. Here, the hollow member 101 may be configured as a part of a processing container of the substrate processing apparatus, or may be inserted into the exhaust portion of the processing container in the substrate processing apparatus. In both cases, a gas stream that contains charged particles at a high flow rate is formed in the hollow member 101, and most of particles may be incorporated by an electrostatic force from the gas stream at the high flow rate into the particle collecting nozzle 102 that takes in a gas at a low flow rate, without being omitted. For this reason, the particles may be introduced into the particle measuring instrument 200 in a state where the concentration rate is very high, thereby highly increasing the measurement accuracy.

In the present exemplary embodiment, the higher the ratio of the inner diameter of the hollow member 101 to the inner diameter of the particle collecting nozzle 102, the larger the concentration rate of particles. However, there is a limitation in an exhaust capacity of a pump configured to form a gas stream in the hollow member 101. A maximum of the ratio of the inner diameter of the hollow member 101 to the inner diameter of the particle collecting nozzle 102 is determined by a ratio of an exhaust capacity of the pump configured to form the gas stream in the hollow member 101 to an exhaust capacity of a pump connected to the particle measuring instrument 200.

### Third Exemplary Embodiment

In the third exemplary embodiment, descriptions will be made on an example of a substrate processing apparatus including the particle measuring device according to the second exemplary embodiment.

### First Example

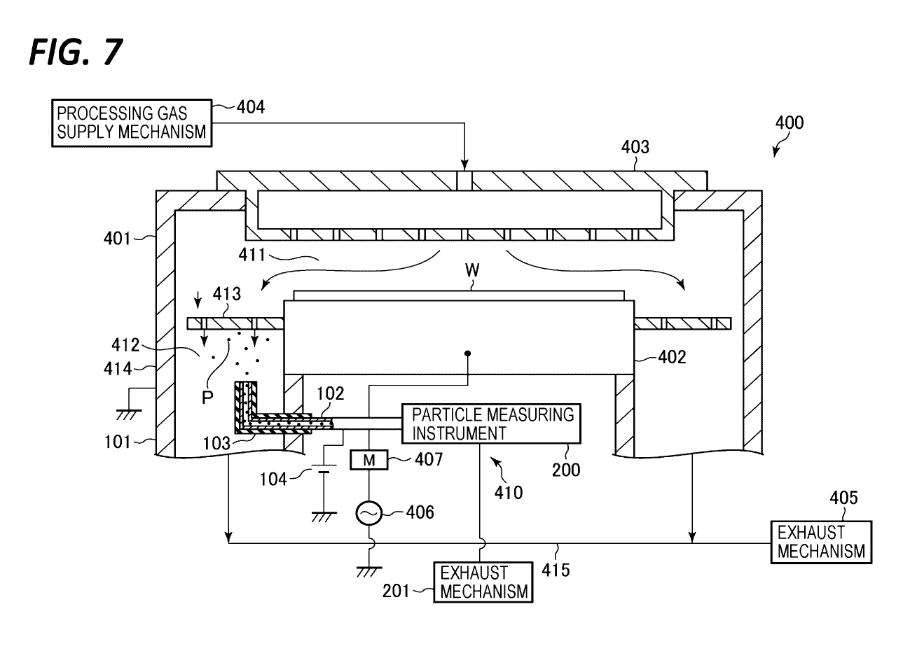

FIG. 7 is a sectional view schematically illustrating a first example of a substrate processing apparatus according to the third exemplary embodiment of the present disclosure.

In the present example, a substrate processing apparatus 400 is configured to perform a plasma etching processing on a semiconductor wafer that is a substrate to be processed and is configured as a plasma etching apparatus.

The substrate processing apparatus 400 includes a processing container 401 that accommodates a semiconductor wafer W to perform a plasma etching processing on the semiconductor wafer W, a placing table 402 on which the semiconductor wafer W is placed within the processing container 401, a shower head 403 provided in the ceiling portion of the processing container 401 to face the placing table 402, a processing gas supply mechanism 404 configured to supply a processing gas into the processing container 401 through the shower head 403, an exhaust mechanism 405 configured to exhaust the inside of the processing container 401, a high-frequency power source 406 configured to supply a high frequency power to the placing table 402, and a particle measuring device 410.

The placing table 402 is connected to the high-frequency power source 406 through a matching unit 407, and functions as a lower electrode. Also, the shower head 403 is supplied with a processing gas from the processing gas supply mechanism 404 and is configured to introduce the supplied processing gas toward the semiconductor wafer W within the processing container 401 in a shower form. The shower head 403 is grounded and functions as an upper electrode. Accordingly, when a high frequency power is applied from the high-frequency power source 406 to the placing table 402 that is a lower electrode, a high frequency electric field is formed between the placing table 402 and the shower head 403 that is an upper electrode. Accordingly, the processing gas introduced into the processing container 401 is generated as plasma, and then, a plasma etching processing is performed on the semiconductor wafer W.

A processing space 411 is formed between the placing table 402 and the shower head 403 within the processing container 401, in which a plasma etching is performed on the semiconductor wafer W. Also, a baffle plate 413 is provided around the placing table 402, a space below the baffle plate 413 within the processing container 401 is formed as an exhaust space 412, and the exhaust space 412 is formed within a cylindrical exhaust portion 414. The exhaust portion 414 is connected to an exhaust pipe 415. When the exhaust mechanism 405 including a vacuum pump is operated, a gas of the processing space 411 is exhausted through the exhaust portion 414. Also, the processing container 401 is grounded.

In the exhaust space 412 within the exhaust portion 414, a gas (exhaust gas) containing particles P negatively charged by plasma flows.

The particle measuring device 410 is basically configured in the same manner as the particle measuring device 300 of the second exemplary embodiment, and includes a hollow member 101, a particle collecting nozzle 102, an insulating member 103, a DC power source 104, and a particle measuring instrument 200. The hollow member 101 is configured by a portion of the processing container 401 including the exhaust portion 414. The inside of the hollow member 101 is exhausted by the exhaust mechanism 405, so that a gas stream is formed. The inlet portion of the particle collecting nozzle 102 is located in the exhaust space below the baffle plate 413. The particle collecting nozzle 102 may be formed in a tubular shape as illustrated, but may be formed in an annular shape corresponding to the annular exhaust portion 414. An exhaust mechanism 201 including a pump is connected to the particle measuring instrument 200. When the exhaust mechanism 201 is operated, a gas is sucked from the particle collecting nozzle 102 at a predetermined flow rate.

By the particle measuring device 410, most of particles generated within the processing container 401 may be measured in real time without being omitted. A gas stream that contains charged particles at a high flow rate is formed in the hollow member 101, and most of particles may be incorporated by an electrostatic force from the gas stream at the high flow rate into the particle collecting nozzle 102 that takes in a gas at a low flow rate without being omitted. For this reason, the particles may be introduced into the particle measuring instrument 200 in a state where the concentration rate is very high, thereby highly increasing the measurement accuracy.

As in the second exemplary embodiment, a maximum of the ratio of the inner diameter of the hollow member 101 to the inner diameter of the particle collecting nozzle 102 is determined by a ratio of an exhaust capacity of the pump of the exhaust mechanism 405 configured to form the gas stream, that is, an exhaust flow, in the hollow member 101 to an exhaust capacity of the pump of the exhaust mechanism 201 connected to the particle measuring instrument 200.

### Second Example

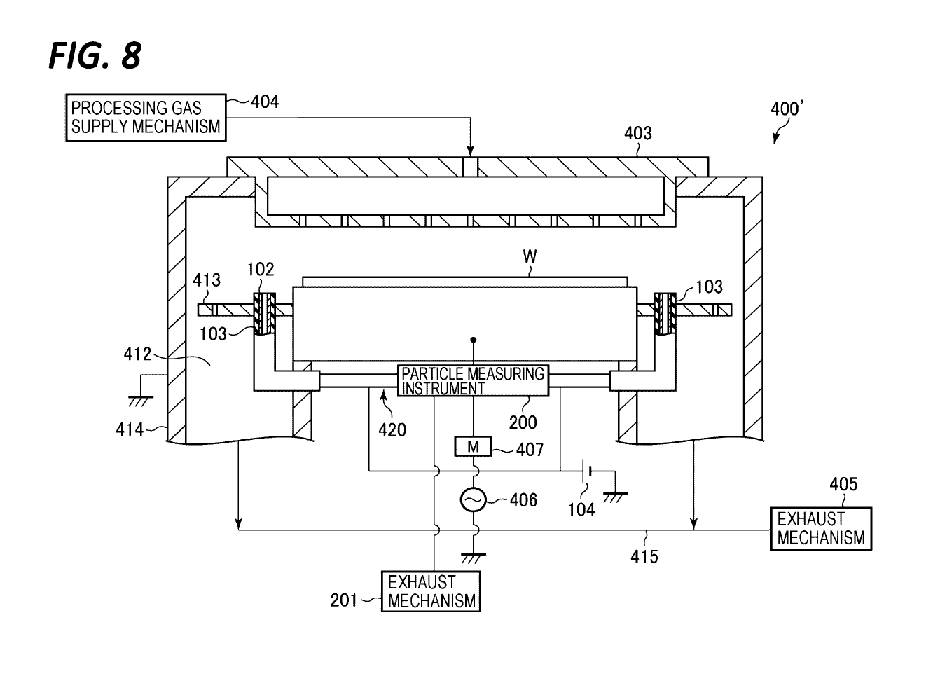

FIG. 8 is a sectional view schematically illustrating a second example of a substrate processing apparatus according to the third exemplary embodiment of the present disclosure.

A substrate processing apparatus 400′ of the present example is basically configured in the same manner as the substrate processing apparatus 400 of the first example, but is different in that instead of the particle measuring device 410, a particle measuring device 420 is provided in which the particle collecting nozzle 102 is formed in an annular shape and its inlet portion is located above the baffle plate 413.

In this manner, the particle measuring device 420 may be not only used for measuring particles but also operated as a dust collector. Also, instead of the annular particle collecting nozzle 102, a plurality of tubular particle collecting nozzles 102 may be provided.

### Third Example

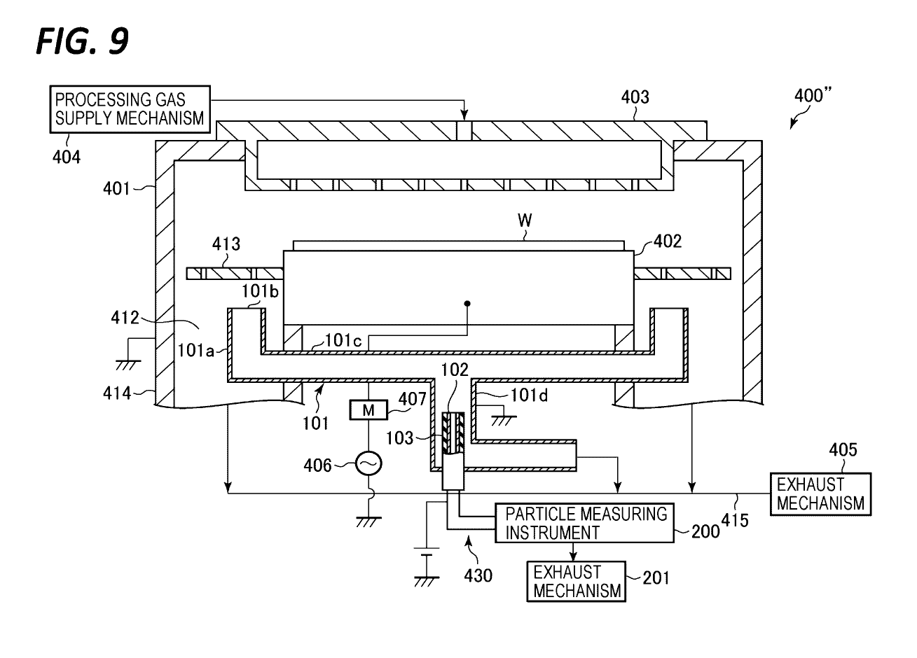

FIG. 9 is a sectional view schematically illustrating a third example of a substrate processing apparatus according to the third exemplary embodiment of the present disclosure.

A substrate processing apparatus 400″ of the present example is basically configured in the same manner as the substrate processing apparatus 400 of the first example, but is different in that instead of the particle measuring device 410, a particle measuring device 430 is provided in which the hollow member 101 is configured as a separate member from the processing container 401.

That is, in the particle measuring device 430 in the substrate processing apparatus 400″ of the present example, the hollow member 101 is formed in an annular shape along the exhaust space within the exhaust space 412. The hollow member 101 includes a distal end member 101a having an opening 101b at the top portion thereof, a horizontal portion 101c connected to the distal end member 101a to horizontally extend to the inner outside of the processing container 401, and a tubular portion 101d extending from the center of the horizontal portion 101c downward. The tubular portion 101d is connected to the exhaust pipe 415. Then, the particle collecting nozzle 102 is inserted into the tubular portion 101d.

As described above, when the hollow member 101 is provided as a separate member from the processing container 401, the hollow member 101 may be applicable to a case where the use of a part of the processing container 401 as an electrode is inconvenient.

### Other Applications

Although the present disclosure has been described by several exemplary embodiments, the present disclosure is not limited to the above described exemplary embodiments, but may be modified in various ways without departing from the gist thereof.

For example, in the exemplary embodiment, it has been described that the particle measuring device using the particle concentration mechanism according to the present disclosure is applied to a plasma etching apparatus as a substrate processing apparatus, and negatively charged particles are concentrated and measured. However, the particle measuring device is not limited thereto, but may be applied to, for example, a film forming apparatus or an annealing apparatus for other substrate processings. Also, the particle measuring device may be applied to a substrate processing apparatus that generates positively charged particles as well as an apparatus that generates negatively charged particles like the plasma etching apparatus. Also, the present disclosure may be applied to a portion where non-charged particles or positive-negative mixed particles are generated. In this case, particles while being charged to one polarity by a charging device may be allowed to flow in a hollow member.

Also, the present disclosure may be applicable to not only the substrate processing apparatus, but also measurement of particles in a wide space such as, for example, a clean room.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A particle concentration mechanism comprising:
a hollow member made of a conductor and having a space therein to which a gas containing particles is guided, and through which the particles in a charged state flow together with the gas;
a particle collecting nozzle made of a conductor which is inserted into the space within the hollow member and configured to collect the charged particles within the hollow member together with the gas;
an insulating member configured to insulate the hollow member from the particle collecting nozzle; and
a DC voltage applying unit configured to apply a DC voltage between the hollow member and the particle collecting nozzle,
wherein, when the DC voltage applying unit applies the DC voltage between the hollow member and the particle collecting nozzle, an electrostatic force directed to an inlet of the particle collecting nozzle acts on the charged particles within the hollow member, and the particles in the hollow member are guided into the particle collecting nozzle and concentrated.

2. The particle concentration mechanism of claim 1, wherein a voltage of the particle collecting nozzle is constant throughout the particle collecting nozzle.

3. The particle concentration mechanism of claim 1, wherein the particle collecting nozzle is formed in a tubular shape to be parallel to the hollow member, and has an opening provided to be perpendicular to a flow of the gas in the hollow member.

4. The particle concentration mechanism of claim 1, wherein the particle collecting nozzle is arranged along a central axis of the hollow member.

5. The particle concentration mechanism of claim 1, wherein the charged particles flowing in the space within the hollow member together with the gas are negatively charged particles, and the DC voltage applying unit applies a low voltage to the hollow member, and a high voltage to the particle collecting nozzle.

6. A particle measuring device comprising:
a hollow member made of a conductor and having a space therein to which a gas containing particles is guided, and through which the particles in a charged state flow together with the gas;
a particle collecting nozzle made of a conductor which is inserted into the space within the hollow member and configured to collect the charged particles within the hollow member together with the gas;
an insulating member configured to insulate the hollow member from the particle collecting nozzle;
a DC voltage applying unit configured to apply a DC voltage between the hollow member and the particle collecting nozzle; and
a particle measuring instrument connected to the particle collecting nozzle to measure the particles collected by the particle collecting nozzle,
wherein, when the DC voltage applying unit applies the DC voltage between the hollow member and the particle collecting nozzle, an electrostatic force directed to an inlet of the particle collecting nozzle acts on the charged particles within the hollow member, and the particles in the hollow member are guided into the particle collecting nozzle and concentrated, and then the concentrated particles are measured by the particle measuring instrument.

7. The particle measuring device of claim 6, wherein a voltage of the particle collecting nozzle is constant throughout the particle collecting nozzle.

8. The particle measuring device of claim 6, wherein the particle collecting nozzle is formed in a tubular shape to be parallel to the hollow member, and has an opening provided to be perpendicular to a flow of the gas in the hollow member.

9. The particle measuring device of claim 6, wherein the particle collecting nozzle is arranged along a central axis of the hollow member.

10. The particle measuring device of claim 6, wherein the charged particles flowing in the space within the hollow member together with the gas are negatively charged particles, and the DC voltage applying unit applies a low voltage to the hollow member, and a high voltage to the particle collecting nozzle.

11. The particle measuring device of claim 6, wherein an exhaust flow of a substrate processing apparatus is introduced into the hollow member.

12. The particle measuring device of claim 11, wherein the substrate processing apparatus is a plasma etching apparatus, an exhaust flow containing negatively charged particles is introduced into the hollow member, and the DC voltage applying unit applies a low voltage to the hollow member, and a high voltage to the particle collecting nozzle.

13. The particle measuring device of claim 11, wherein the hollow member constitutes a portion of a processing container of the substrate processing apparatus to cause the exhaust flow to directly flow therein.

14. The particle measuring device of claim 11, wherein the hollow member is configured separately from a processing container of the substrate processing apparatus, and is inserted into the processing container so that the exhaust flow is introduced into the hollow member.

15. The particle measuring device of claim 6, wherein the particle measuring instrument is an LPN or a CNC.

16. The particle measuring device of claim 6, wherein a maximum of a ratio of an inner diameter of the hollow member to an inner diameter of the particle collecting nozzle is determined by a ratio of an exhaust capacity of a pump configured to form a gas stream within the hollow member to an exhaust capacity of a pump configured to guide the gas containing the particles to the particle measuring instrument.

17. A substrate processing apparatus comprising:
a processing container configured to accommodate a substrate to be processed therein;
a processing gas supply mechanism configured to supply a processing gas into the processing container;
an exhaust mechanism configured to exhaust the processing container; and
a particle measuring device configured to collect an exhaust flow containing charged particles formed within the processing container exhausted by the exhaust mechanism, and measure the particles,
wherein the particle measuring device includes:
a hollow member made of a conductor, into which the exhaust flow is introduced;
a particle collecting nozzle made of a conductor which is inserted into a space within the hollow member and configured to collect the charged particles within the hollow member together with the gas;
an insulating member configured to insulate the hollow member from the particle collecting nozzle; and
a DC voltage applying unit configured to apply a DC voltage between the hollow member and the particle collecting nozzle,
a particle measuring instrument connected to the particle collecting nozzle to measure the particles collected by the particle collecting nozzle,
wherein, when the DC voltage applying unit applies the DC voltage between the hollow member and the particle collecting nozzle, an electrostatic force directed to an inlet of the particle collecting nozzle acts on the charged particles within the hollow member, and the particles in the hollow member are guided into the particle collecting nozzle and concentrated, and then the concentrated particles are measured by the particle measuring instrument.

18. The substrate processing apparatus of claim 17, wherein the exhaust flow is introduced into the hollow member from the processing container.

19. The substrate processing apparatus of claim 18, wherein the substrate processing apparatus is a plasma etching apparatus, an exhaust flow containing negatively charged particles is introduced into the hollow member, and the DC voltage applying unit applies a low voltage to the hollow member, and a high voltage to the particle collecting nozzle.

20. The substrate processing apparatus of claim 18, wherein the hollow member constitutes a portion of the processing container to cause the exhaust flow to directly flow therein.

21. The substrate processing apparatus of claim 18, wherein the hollow member is configured separately from the processing container, and is inserted into the processing container so that the exhaust flow is introduced into the hollow member.

22. The substrate processing apparatus of claim 17, wherein a placing table configured to place the substrate to be processed thereon is arranged within the processing container, the processing container includes an annular exhaust space around the placing table, an annular baffle plate is provided above the exhaust space, the particle collecting nozzle is provided in an annular form along the exhaust space above the baffle plate, or provided as a plurality of tubular particle collecting nozzles, and the particle collecting nozzle is sucked toward the particle measuring instrument to have a dust collecting function within the processing container.

23. The substrate processing apparatus of claim 17, wherein the particle measuring instrument is an LPN or a CNC.

24. The substrate processing apparatus of claim 18, wherein a maximum of a ratio of an inner diameter of the hollow member to an inner diameter of the particle collecting nozzle is determined by a ratio of an exhaust capacity of a pump configured to form the exhaust flow within the hollow member to an exhaust capacity of a pump configured to guide the gas containing the particles to the particle measuring instrument.
